(19) United States
(12) Patent Application Publication
(10) Pub. No.: US 2011/0006368 A1
(43) Pub. Date: Jan. 13, 2011

(54) SEMICONDUCTOR WAFER, METHOD OF MANUFACTURING A SEMICONDUCTOR WAFER, AND ELECTRONIC DEVICE

(75) Inventors: Masahiko Hata, Tsuchiura-shi (JP); Tomoyuki Takada, Tsukuba-shi (JP)

Correspondence Address: SUGHRUE MION, PLLC, 2100 PENNSYLVANIA AVENUE, N.W., SUITE 800, WASHINGTON, DC, 20037, US

(73) Assignee: Sumitomo Chemical Company, Limited, Chuo-ku, Tokyo (JP)

(21) Appl. No.: 12/920,457

(22) PCT Filed: Feb. 27, 2009
(86) PCT No.: PCT/JP2009/000921

§ 371 Date: Aug. 31, 2010

(30) Foreign Application Priority Data
Mar. 1, 2008 (JP) 2008-051449

(51) Int. Cl. H01L 29/786; H01L 29/30; H01L 21/20

(52) U.S. Cl. 257/347; 257/617; 438/481; 257/E29.106; 257/E21.09; 257/E29.273

(57) ABSTRACT

The objective is to improve capabilities such as high-speed switching of a compound semiconductor device. Provided is a semiconductor wafer comprising a silicon wafer; an insulating film that is formed on the silicon wafer and that includes an open portion reaching the silicon wafer and having an aspect ratio of √3/3 or more; a seed compound semiconductor crystal that is formed in the open portion and that protrudes beyond a surface of the insulating film; and a laterally grown compound semiconductor layer that is laterally grown on the insulating film with a specified surface of the seed compound semiconductor crystal as a seed surface.

### TECHNICAL FIELD

The present invention relates to a semiconductor wafer, a method of manufacturing a semiconductor wafer, and an electronic device. In particular, the present invention relates to a semiconductor wafer, a method of manufacturing a semiconductor wafer, and an electronic device including a compound semiconductor crystal thin film having good crystallinity formed on an insulating film using an inexpensive silicon wafer.

### BACKGROUND ART

Various types of high-performance electronic devices are being developed that use heterojunctions in electronic devices therein made of compound semiconductor crystals such as GaAs. Since the capabilities of these high-performance electronic devices are influenced by the crystallinity of the compound semiconductor crystals included therein, high quality compound semiconductor crystals are desired. The need for lattice matching at the heterointerfaces in thin film crystal growth for manufacturing electronic devices using GaAs-based compound semiconductor crystals leads to the selection of wafers made of GaAs or of materials such as Ge whose lattice constant is very close to that of GaAs.

Patent Document 1 discloses a semiconductor device that has sections that restrict epitaxial regions grown on a non-matching wafer or a wafer with a high dislocation defect density.

Patent Document 1: Japanese Patent Application Publication No. 4-233720

### DISCLOSURE OF THE INVENTION

### Problems to be Solved by the Invention

When manufacturing GaAs-based electronic devices, lattice matching is considered and a GaAs wafer or a wafer that can achieve lattice matching with GaAs, such as a Ge wafer, is selected, as described above. However, GaAs wafers or wafers such as Ge wafers that can achieve lattice matching with GaAs are expensive, and this increases the overall cost of the device. Furthermore, these wafers do not have sufficient heat dissipation characteristics, and this might result in limitations such as restrictions on the formation density of the devices in order to achieve a reliable thermal design or only using the devices in a temperature range for which heat dissipation can be achieved. Accordingly, there is a demand for a semiconductor wafer that can be manufactured using an inexpensive Si wafer with good heat dissipation characteristics and that has a high-quality GaAs-type crystal thin film. One example of a GaAs epitaxial layer with low dislocation density formed on a Ge-coated Si wafer using lateral epitaxial overgrowth is described in B. Y. Tsaur, et al., “Low-dislocation-density GaAs epilayers grown on Ge-coated Si substrates by means of lateral epitaxial overgrowth,” Appl. Physics Lett. 41(4)347-349, Aug. 15, 1982.

However, a sufficiently high-quality semiconductor substrate formed using an Si wafer and having a crystal thin film made of a compound semiconductor such as GaAs has yet to be achieved. A semiconductor wafer having good crystallinity is desired to achieve a high-performance electronic device.

### Means for Solving the Problems

In order to solve the above problems, the inventors created the present invention as a result of rigorous examination. According to a first embodiment of the present invention, provided is a semiconductor wafer comprising a silicon wafer; an insulating film that is formed on the silicon wafer and that includes an open portion reaching the silicon wafer and having an aspect ratio of √3/3 or more; a seed compound semiconductor crystal that is formed in the open portion and that protrudes beyond a surface of the insulating film; and a laterally grown compound semiconductor layer that is laterally grown on the insulating film with a specified surface of the seed compound semiconductor crystal as a seed surf ice. The aspect ratio can be 1 or more when the surface orientation of the silicon wafer is (100), can be √2 (approximately 1.414) or more when the surface orientation of the silicon wafer is (111), and can be √3/3 (approximately 0.577) or more when the surface orientation of the silicon wafer is (110).

The aspect ratio of the open portion refers to a value obtained by dividing the depth of the open portion by the width of the open portion. This Specification uses the technical definition of “aspect ratio” as described in “Handbook for Electronics, Information and Communication Engineers Vol. I,” Institute of Electronics, Information, and Communication Engineers, Ohmsha publishing, 1988, pg. 751, where the aspect ratio is defined as “etching depth/pattern width.” The depth of the open portion is in the layering direction when layers are formed on the silicon wafer, and the width of the open portion is in a direction perpendicular to the layering direction. If the open portion has a plurality of widths, the smallest width is used when calculating the aspect ratio. For example, when the shape of the open portion as seen in the direction of the layering is a rectangle, the length of a short side of the rectangle is used to calculate the aspect ratio.

The shape of the open portion as seen in the direction of the layering may be any shape, examples of which include a square, a rectangle, a stripe, a circle, and an oval. When the shape is a circle or an oval, the width of the open portion is respectively the diameter and the shortest diameter. Furthermore, the open portion may have any cross-sectional shape in the direction of the layering, examples of which include a rectangular shape, a parabolic trapezoid shape, and a hyperbolic shape. If the cross-sectional shape is a trapezoid, the width of the open portion is whichever is the smallest of the width at the bottom thereof and the width at the top thereof.

If the shape of the open portion as seen in the layering direction is a rectangle or a square and the cross-sectional shape in the layering direction is rectangular, the stereoscopic shape in the open portion can be regarded as a rectangular parallelepiped. However, the stereoscopic shape within the open portion may be any shape, and when calculating the aspect ratio for an open region with an arbitrary stereoscopic shape, this shape may be approximated as a rectangular parallelepiped.

In the first embodiment, the open portion may have a maximum width no greater than 5 μm in a direction parallel to a surface of the silicon wafer. The seed compound semiconductor crystal may include a first seed compound semiconductor that is formed in the open portion to protrude beyond the surface of the insulating film and a second seed compound semiconductor that is laterally grown on the insulating film with a specified surface of the first seed compound semiconductor as a nucleus, and the seed surface may be a specified surface of the second seed compound semiconductor. The laterally grown compound semiconductor layer or the seed compound semiconductor crystal may include defect regions that contain defects, and arrangement of the defect regions may be controlled by defect cores formed at prescribed intervals on the insulating film or on the seed surface.

The laterally grown compound semiconductor layer may include defect regions that contain defects, and arrangement of the defect regions may be controlled by forming a plurality of the open portions at prescribed intervals. A plurality of the open portions may be formed in the insulating film and a plurality of the laterally grown compound semiconductor layers may be crystal-grown to be separated from each other on the insulating film, with specified surfaces of the seed compound semiconductor crystals formed in the open portions as seed surfaces. The laterally grown compound semiconductor layer may include a group 2-6 compound semiconductor or a group 3-5 compound semiconductor.

According to a second embodiment of the present invention, provided is a semiconductor wafer comprising a silicon wafer; an insulating film that is formed on the silicon wafer and that includes an open portion having an aspect ratio of √3/3 or more; a seed compound semiconductor crystal that is formed in the open portion; and a compound semiconductor layer that is formed on the insulating film and that lattice matches or pseudo-lattice matches with the seed compound semiconductor crystal.

According to a third embodiment of the present invention, provided is a semiconductor wafer comprising a silicon wafer; an insulating film that is formed on the silicon wafer and that includes an opening reaching the silicon wafer and having an aspect ratio of √3/3 or more; a compound semiconductor crystal that is formed in the opening and that protrudes beyond a surface of the insulating film; and a laterally grown compound semiconductor that is laterally grown on the insulating film with the compound semiconductor crystal as a seed. In this case, the compound semiconductor crystal may include a first seed compound semiconductor that is formed in the opening to protrude beyond the surface of the insulating film and a second seed compound semiconductor that is laterally gown on the insulating film with the first seed compound semiconductor as a nucleus.

According to a fourth embodiment of the present invention, provided is a semiconductor wafer comprising a silicon wafer; an insulating film that is formed on the silicon wafer and that includes an opening having an aspect ratio of √3/3 or more; a compound semiconductor crystal that is formed in the opening; and a compound semiconductor layer that is formed on the insulating film and that lattice matches or pseudo-lattice matches with the compound semiconductor crystal.

According to a fifth embodiment of the present invention, provided is a semiconductor wafer comprising an insulating film that is formed on a silicon wafer and that includes an opening having an aspect ratio of √3/3 or more; a first compound semiconductor that is formed in the opening; and a second compound semiconductor that is grown at least on the insulating film with the first compound semiconductor as a nucleus.

In the first through fifth embodiments, when forming the seed compound semiconductor crystal in the open portion, after forming the compound semiconductor buffer layer at a temperature no greater than 550° C., preferably no greater than 500° C., the temperature may be raised to form the seed compound semiconductor crystal. Furthermore, the seed compound semiconductor crystal may be formed after processing the surface of the compound semiconductor buffer layer or the bottom of the open portion with a gas containing P, such as PH₃.

According to a sixth embodiment of the present invention, provided is a method of manufacturing a semiconductor wafer, comprising forming an insulating film on a silicon wafer; forming, in the insulating film, an open portion reaching the silicon wafer and having an aspect ratio of √3/3 or more; forming a seed compound semiconductor crystal in the open portion that protrudes beyond a surface of the insulating film; and laterally growing a laterally grown compound semiconductor layer on the insulating film with a specified surface of the seed compound semiconductor crystal as a seed surface.

In the sixth embodiment, forming the seed compound semiconductor crystal may include forming in the open portion a first seed compound semiconductor that protrudes beyond the surface of the insulating film; and laterally growing a second seed compound semiconductor on the insulating film, with a specified surface of the first seed compound semiconductor as a nucleus, and forming a specified surface of the second seed compound semiconductor as the seed surface. This method may further comprise forming defect cores at prescribed intervals on the seed surface of the seed compound semiconductor crystal, the seed surface of the second seed compound semiconductor, or the insulating film.

According to a seventh embodiment of the present invention, provided is a method of manufacturing a semiconductor wafer, comprising forming an insulating film on a silicon wafer; forming, in the insulating film, an opening reaching the silicon wafer and having an aspect ratio of √3/3 or more; forming a compound semiconductor crystal in the opening that protrudes beyond a surface of the insulating film; and laterally growing a laterally grown compound semiconductor on the insulating film, with the compound semiconductor crystal as a seed.

According to an eighth embodiment of the present invention, provided is a method of manufacturing a semiconductor wafer, comprising forming, on a silicon wafer, an insulating film that includes an opening having an aspect ratio of √3/3 or more; forming a first compound semiconductor in the opening; and forming a second compound semiconductor at least on the insulating film with the first compound semiconductor as a nucleus.

According to a ninth embodiment of the present invention, provided is an electronic device comprising a silicon wafer; an insulating film that is formed on the silicon wafer and that includes an open portion reaching the silicon wafer and having an aspect ratio of √3/3 or more; a seed compound semiconductor crystal that is formed in the open portion and that protrudes beyond a surface of the insulating film; a laterally grown compound semiconductor layer that is laterally gown on the insulating film with a specified surface of the seed compound semiconductor crystal as a seed surface; and an active element that has an active region and that is formed on a defect-free region of the laterally grown compound semiconductor layer.

In the ninth embodiment, the active element may have a first input/output electrode and a second input/output electrode, and the first input/output electrode may cover a growth surface of the laterally grown compound semiconductor layer. The active element may have a first input/output electrode and a second input/output electrode, the laterally grown compound semiconductor layer in a region containing the open portion may be removed by etching, and the second input/output electrode may cover a side surface of the laterally grown compound semiconductor layer that is exposed by the etching. The second input/output electrode may be connected to the silicon wafer via the seed compound semiconductor crystal formed in the open portion of the insulating film exposed by the etching. The active element may have control electrodes that control voltage or current between input and output, and the control electrodes may be formed (i) between the insulating film and the laterally grown compound semiconductor layer and (ii) on a side of the laterally grown compound semiconductor layer that is opposite the insulating film, in a manner to face each other. A plurality of the active elements may be connected to each other.

According to a tenth embodiment of the present invention, provided is an electronic device comprising a silicon wafer; an insulating film that is formed on the silicon wafer and that includes an opening reaching the silicon wafer and having an aspect ratio of √3/3 or more; a compound semiconductor crystal that is formed in the opening and that protrudes beyond a surface of the insulating film; a laterally grown compound semiconductor that is laterally grown on the insulating film with the compound semiconductor crystal as a seed; and an active element having an active region on the laterally grown compound semiconductor.

According to an eleventh embodiment of the present invention, provided is an electronic device comprising an insulating film that is formed on a silicon wafer and that includes an opening having an aspect ratio of √3/3 or more; a first compound semiconductor that is formed in the opening; a second compound semiconductor that is grown at least on the insulating film with the first compound semiconductor as a nucleus; and an active element having an active region on the second compound semiconductor.

### BRIEF DESCRIPTION OF THE DRAWINGS

FIG. 1 is an exemplary planar view of an electronic device 100 according to an embodiment of the present invention.

FIG. 2 is a cross-sectional view taken along the line A-A in FIG. 1.

FIG. 3 is a cross-sectional view taken along the line B-B in FIG. 1.

FIG. 4 is an exemplary cross-sectional view of a step for manufacturing the electronic device 100.

FIG. 5 is an exemplary cross-sectional view of a step for manufacturing the electronic device 100.

FIG. 6 is an exemplary cross-sectional view of a step for manufacturing the electronic device 100.

FIG. 7 is an exemplary cross-sectional view of a step for manufacturing the electronic device 100.

FIG. 8 is an exemplary planar view of an electronic device 200 according to another embodiment of the present invention.

FIG. 9 is an exemplary planar view of an electronic device 300 according to another embodiment of the present invention.

FIG. 10 is an exemplary planar view of an electronic device 400 according to another embodiment of the present invention.

FIG. 11 is an exemplary cross-sectional view of an electronic device 500 according to another embodiment of the present invention.

FIG. 12 is an exemplary cross-sectional view of an electronic device 600 according to another embodiment of the present invention.

FIG. 13 is an exemplary cross-sectional view of an electronic device 700 according to another embodiment of the present invention.

### LIST OF REFERENCE NUMERALS

100 Electronic device
102 Silicon wafer
104 Insulating film
105 Open portion
108 First seed compound semiconductor
110 Second seed compound semiconductor
112 Laterally grown compound semiconductor layer
114 Gate insulating film
116 Gate electrode
118 Source/drain electrode
120 Defeat region
130 Defect region
200 Electronic device
300 Electronic device
400 Electronic device
402 Buffer layer
500 Electronic device
502 Source/drain electrode
600 Electronic device
602 Source/drain electrode
700 Electronic device
702 Lower gate insulating film
704 Lower gate electrode

### BEST MODE FOR CARRYING OUT THE INVENTION

Hereinafter, some embodiments of the present invention will be described. The embodiments do not limit the invention according to the claims, and all the combinations of the features described in the embodiments are not necessarily essential to means provided by aspects of the invention.

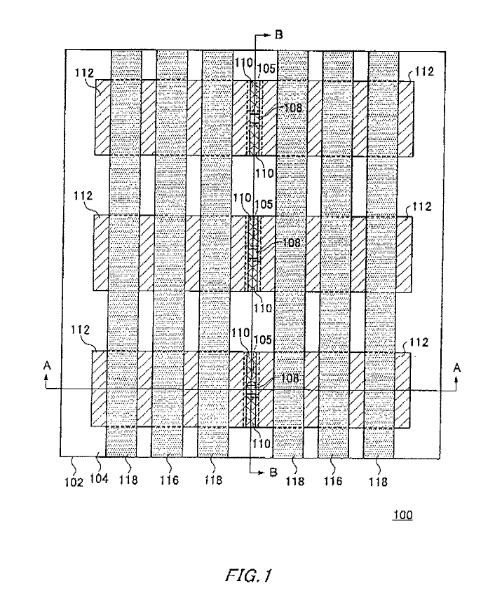

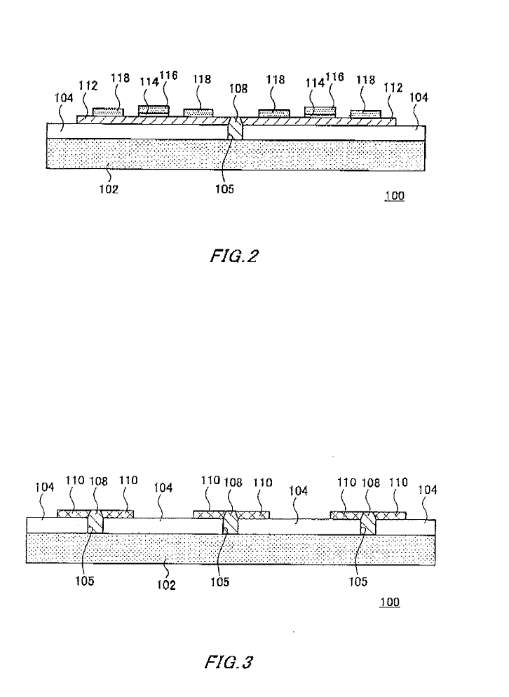

FIG. 1 is an exemplary planar view of an electronic device 100 according to an embodiment of the present invention. FIG. 2 is a cross-sectional view taken along the line A-A in FIG. 1. FIG. 3 is a cross-sectional view taken along the line B-B in FIG. 1. The electronic device 100 of the present embodiment includes a silicon wafer 102, insulating films 104, first seed compound semiconductors 108, second seed compound semiconductors 110, laterally grown compound semiconductor layers 112, gate insulating films 114, gate electrodes 116, and source/drain electrodes 118. The following describes, as an example of the electronic device 100, a device that includes a plurality of MOSFETs (metal-oxide-semiconductor field-effect transistors).

The silicon wafer 102 may be a commercially available silicon wafer, and MOSFETs or the like may be formed on the silicon wafer 102 as active elements. Since the silicon wafer 102 is used as the wafer in the present embodiment, the resulting electronic device 100 has favorable cost performance. Furthermore, since the silicon wafer 102 is used, heat dissipation by the electronic device 100 can be easily managed.

The insulating films 104 may be formed on the silicon wafer 102. The insulating films 104 include open portions that reach the silicon wafer 102 and that have aspect ratios no less than √3/3. These “open portions” may be referred to as “openings,” and an open portion 105 is an example of an opening. The maximum width, in a direction parallel to the surface of the silicon wafer 102, of each open portion 105 formed in an insulating film 104 can be no greater than 5 μm and no less than 2 μm. The insulating film 104 functions as an inhibiting layer that inhibits epitaxial growth. In other words, epitaxially-grown film can be deposited selectively within the open portions 105 that expose the silicon, and the epitaxial film can be prevented from being grown on the insulating film 104.

Each insulating film 104 may be a silicon oxide film or a silicon nitride film, for example. The surface of the silicon wafer 102 exposed at the bottom of the open portions 105 may be processed with a gas containing P, such as PH₃ (phosphine). In such a case, the crystallinity of the films formed in the open portions 105 can be improved.

The insulating films 104 may be formed separately from each other on the silicon wafer 102. That is, a plurality of insulating films 104 may be formed on the silicon wafer 102. As a result, the silicon wafer 102 is exposed between the insulating films 104, and the exposed portions of the silicon wafer 102 function as adsorbing sections. The adsorbing sections are regions that adsorb the film growth precursor during epitaxial growth, and stabilize the film deposition rate during epitaxial growth. When the insulating films 104 are separated from each other, the distance between adjacent insulating films 104 is preferably between 20 μm and 500 μm. As a result of experimentation by the present inventors, a stable epitaxial growth rate was achieved by arranging the insulating films 104 separated by the above distances. One or more of the open portions 105 may be formed in each insulating film 104. The plurality of insulating films 104 may be formed on the silicon wafer 102 at uniform intervals.

The first seed compound semiconductors 108 are formed in the open portions 105 to protrude further than the surfaces of the insulating films 104. In other words, the first seed compound semiconductors 108 are formed in the open portions 105, and the tops of first seed compound semiconductors 108 are formed above the surfaces of the insulating films 104. Instead, the tops of the first seed compound semiconductors 108 may protrude beyond the surfaces of the insulating films 104. The portion protruding from the surface of each insulating film 104 has a specified surface formed thereon to serve as the seed surface. The first seed compound semiconductors 108 are selectively grown within open portions 105 that are formed in the insulating films 104 and whose aspect ratios are no less than √3/3, thereby improving the crystallinity of the first seed compound semiconductors 108.

When a first seed compound semiconductor 108 is selectively grown to a certain thickness in an open portion 105 whose aspect ratio is no less than √3/3, the crystal defects in the first seed compound semiconductor terminate at the walls of the open portion 105. Therefore, the first seed compound semiconductor 108 formed within the open portion 105 has good crystallinity in the upper portion thereof. The first seed compound semiconductor 108 in the open portion 105 becomes the crystal nucleus of a second seed compound semiconductor 110, and so can improve the crystallinity of the second seed compound semiconductor 110.

The aspect ratio of each open portion can be greater than or equal to √3/3. In particular, when the surface orientation of the silicon wafer 102 is (100), the aspect ratio is preferably no less than 1, and when the surface orientation of the silicon wafer 102 is (111), the aspect ratio is preferably no less than 42, which is approximately 1.414. When the surface orientation of the silicon wafer 102 is (110), the aspect ratio is preferably no less than √3/3, which is approximately 0.577.

The second seed compound semiconductors 110 are laterally grown on the insulating films 104, with the specified surfaces of the first seed compound semiconductors serving as the crystal nuclei. The second seed compound semiconductors 110 may be compound semiconductors from group 4, group 3-5, or group 2-6 that lattice match or pseudo-lattice match with the specified surfaces of the first seed compound semiconductors 108, examples of which include GaAs, InGaAs, and SiC. The specified surfaces of the second seed compound semiconductors 110 provide seed surfaces that can serve as the crystal nuclei of the laterally grown compound semiconductor layers 112. Since the second seed compound semiconductors 110 have improved crystallinity as described above, the second seed compound semiconductors 110 can provide seed surfaces with good crystallinity.

Pseudo-lattice matching means that there is only a small difference between the lattice constants of the two semiconductor layers in contact with each other, and so, although this is not complete lattice matching, the lattice matching is close enough that the occurrence of defects due to lattice mismatching is negligible, and so these two contacting semiconductor layers can be considered to be in a layered state. For example, the layered state of the Ge layer and the GaAs layer can be considered as pseudo-lattice matching.

The first seed compound semiconductors 108 and the second seed compound semiconductors 110 can be understood as integrally forming seed compound semiconductor crystals. Specifically, the first seed compound semiconductors 108 and the second seed compound semiconductors 110 may be compound semiconductor crystals formed in the open portions 105, and may be seed compound semiconductor crystals formed to protrude beyond the surfaces of the insulating films 104. Specified surfaces of the second seed compound semiconductors 110 may be the seed surfaces of the seed compound semiconductor crystals.

The laterally grown compound semiconductor layers 112 are laterally grown on the insulating films 104, with the specified surfaces of the second seed compound semiconductors 110 or the seed compound semiconductor crystals serving as the seed surfaces. Since the laterally grown compound semiconductor layers 112 are crystal-grown with the specified surfaces of the second seed compound semiconductors 110 or the seed compound semiconductor crystals having good crystallinity serving as the seed surfaces, the resulting semiconductor layers have good crystallinity. Therefore, the laterally grown compound semiconductor layers 112 include defect-free regions. The laterally grown compound semiconductor layers 112 may include group 2-6 compound semiconductors or group 3-5 compound semiconductors. GaAs layers are an example of the laterally grown compound semiconductor layers 112. Here, the “defect-free region” refers to a region that does not include dislocation, such as edge dislocation and screw dislocation, occurring when layering crystals having different properties, such as lattice constants and thermal expansion coefficients. In addition to regions that include absolutely no defects, the defect-free regions may be regions with lower defect density than defect regions.

When a silicon wafer 102 having a (100) surface as a principal surface is used and a compound semiconductor is laterally grown on the (100) surface of the silicon wafer 102, the compound semiconductor is more easily grown in the <011> direction of the silicon wafer 102 than in the <0-11> direction. When growing the compound semiconductor in the <0-11> direction of the silicon wafer 102, a (111) B surface of the compound semiconductor appears on an end surface of the laterally grown compound semiconductor. This (111) B surface is stable, and can therefore be easily formed as a flat surface. Accordingly, an electronic device can be formed by forming a gate insulating film, a source electrode, a gate electrode, and a gain electrode on the (111) B surface of the compound semiconductor.

When laterally growing the compound semiconductor in the <011> direction of the silicon wafer 102, the (111) B surface of the compound semiconductor appearing on an end surface of the laterally-grown compound semiconductor faces the opposite direction. In this case, the upper portion of the (100) surface can be widened so that the electronic device can be formed on the (100) surface. The compound semiconductor can be laterally grown in both the <010> direction and the <001> direction of the silicon wafer 102 under a condition of a high partial pressure of arsine. When grown in these directions, a (110) surface or a (101) surface of the compound semiconductor is likely to appear on an end surface of the compound semiconductor. An electronic device can also be formed by forming a gate insulating film, a source electrode, a gate electrode, and a gain electrode on the (110) surface or the (101) surface of the compound semiconductor.

The silicon wafer 102, the insulating films 104, the first seed compound semiconductors 108, the second seed compound semiconductors 110, and the laterally grown compound semiconductor layers 112 described above can be understood as the components of the semiconductor wafer. Expressed in different terms, the semiconductor wafer includes the silicon wafer 102, insulating films 104 formed on the insulating wafer and including open portions with aspect ratios no less than √3/3, seed compound semiconductor crystals formed in the open portions 105, and compound semiconductor layers that are formed on the insulating films 104 and lattice match or pseudo-lattice match with the seed compound semiconductor crystals. The seed compound semiconductor crystals can include the first seed compound semiconductors 108 and the second seed compound semiconductors 110, and the compound semiconductor layers may be the laterally grown compound semiconductor layers 112.

Active elements having active regions can be formed on the defect-free regions of the laterally grown compound semiconductor layers 112. The active elements may be MOSFETs that each include a gate insulating film 114, a gate electrode 116, and a source/drain electrode 118. The MOSFETs may instead be MISFETs (Metal-Insulator-Semiconductor Field-Effect Transistors).

Each gate insulating film 114 electrically insulates the gate electrode 116 from the laterally grown compound semiconductor layer 112. The gate insulating films 114 may be silicon oxide films, silicon nitride films, or aluminum oxide films, for example.

The gate electrodes 116 are examples of control electrodes. Each gate electrode 116 controls the current or voltage between input and output, which is exemplified here as the source and drain. The gate electrodes 116 may be semiconductors made of metals such as aluminum, copper, gold, silver, platinum, tungsten, etc. or of highly doped silicon, for example.

The source/drain electrodes 118 are examples of input/output electrodes. Each source/drain electrode 118 contacts a source region and a drain region. The source/drain electrodes 118 may be semiconductors made of metals such as aluminum, copper, gold, silver, platinum, tungsten, etc. or of highly doped silicon, for example.

Although not shown, source and drain regions are formed below each source/drain electrode 118. A channel layer formed below each gate electrode 116 and having a channel region between the source region and the drain region may be a laterally grown compound semiconductor layer 112, or may be a layer formed on top of the laterally grown compound semiconductor layer 112. Buffer layers may be formed between the laterally grown compound semiconductor layers 112 and the channel layers. The channel layers or the buffer layers may be GaAs layers, InGaAs layers, AlGaAs layers, GaN layers, InGaP layers, or ZnSe layers, for example.

The electronic device 100 shown in FIG. 1 includes six MOSFETs. Among these six MOSFETs, three are connected to each other by the wiring of the gate electrodes 116 and the source/drain electrodes 118. The laterally grown compound semiconductor layers 112, which are crystal-grown using the first seed compound semiconductors 108 formed on the silicon wafer 102 in the open portions 105 of the insulating films 104 as nuclei, may be separated from each other on the insulating films 104.

Since the laterally grown compound semiconductor layers 112 are separated from each other, interfaces are not formed between adjacent laterally grown compound semiconductor layers 112, and so crystal defects occurring at these interfaces need not be regarded as a problem. As long as the active elements formed on the laterally grown compound semiconductor layers 112 should exhibit good crystallinity in the active layers thereof, problems do not occur when the laterally grown compound semiconductor layers 112 are formed separately. If an increase in the drive current of each active element is desired, it is sufficient to connect the active elements to each other in parallel as shown in the present embodiment. In the electronic device shown in FIGS. 1 to 3, two MOSFETs are formed sandwiching each open portion 105, but instead, the two MOSFETs may be separated by removing the compound semiconductor layer therebetween using etching or the like, or by deactivating the compound semiconductor layer using ion implantation or the like.

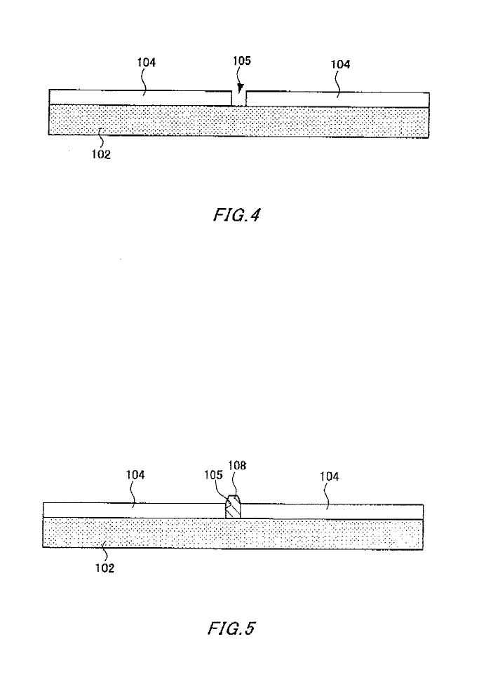

FIGS. 4 to 7 are exemplary cross-sectional views of steps for manufacturing the electronic device 100. As shown in FIG. 4, the insulating films 104 are formed on the silicon wafer 102, and an open portion 105 reaching the silicon wafer 102 and having an aspect ration no less than √3/3 is formed between the insulating films 104. The insulating films can be formed by CVD (Chemical Vapor Deposition) or a sputtering technique, and the open portion 105 in the insulating films 104 can be formed by photolithography.

As shown in FIG. 5, the first seed compound semiconductor 108 is formed in the open portion 105 of the insulating films 104 to be above the surfaces of the insulating films 104. In other words, the first seed compound semiconductor 108 is formed to protrude beyond the surfaces of the insulating films 104. When the first seed compound semiconductor 108 is formed of GaAs, for example, an epitaxial growth method using MOCVD or MBE can be used. In this case, the raw material gas may be TM-Ga (trimethylgallium), AsH₃ (arsine), or some other gas. The growth temperature may be between 600° C. and 650° C.

Next, the second seed compound semiconductor 110 is laterally grown on the insulating films 104 using a specified surface of the first seed compound semiconductor 108 as a seed surface. The cross-sectional view for this step is the same as shown in FIG. 3. When the second seed compound semiconductor 110 is formed of GaAs, for example, an epitaxial growth method using MOCVD or MBE can be used. In this case, the raw material gas may be TM-Ga (trimethylgallium), AsH₃ (arsine), or some other gas. The growth temperature may be between 600° C. and 650° C.

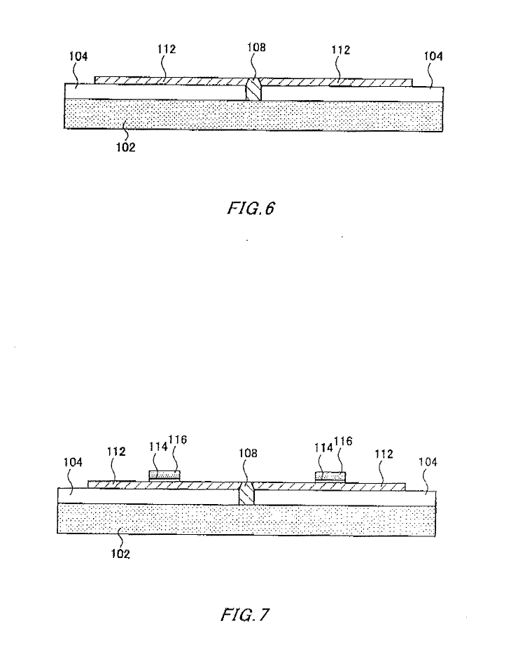

As shown in FIG. 6, the laterally grown compound semiconductor layers 112 are laterally grown on the insulating films 104, with the specified surfaces of the second seed compound semiconductor 110 serving as the seed surfaces. When the laterally grown compound semiconductor layers 112 are formed of GaAs, for example, an epitaxial growth method using MOCVD or MBE can be used. In this case, the raw material gas may be TM-Ga (trimethylgallium), AsH₃ (arsine), or some other gas.

In order to accelerate the lateral growth when forming the laterally grown compound semiconductor layers 112 on the wafer with a (001) surface, low-temperature growth is preferably selected, specifically a temperature no greater than 700° C., preferably no greater than 650° C. When the lateral growth is in the <110> direction, high AsH₃ pressure is preferably used, e.g. AsH₃ pressure of no less than 0.1 kPa. As a result, the growth rate in the <110> direction is greater than the growth rate in the <−110> direction.

As shown in FIG. 7, an insulating film that becomes the gate insulating films 114 and a conductive film that becomes the gate electrodes 116 are sequentially formed on the laterally grown compound semiconductor layers 112, and the insulating film and conductive film are patterned using photolithography, for example. As a result, the gate insulating films 114 and the gate electrodes 116 are formed. After this, a conductive film that becomes the source/drain electrodes 118 is formed and then patterned using photolithography, for example, to manufacture the electronic device 100 shown in FIG. 2.

With the electronic device 100 described above, since the first seed compound semiconductors 108 are formed in the open portions 105 with aspect ratios no greater than √3/3 in the insulating films 104, the crystallinity of the first seed compound semiconductors 108 can be improved. This improvement to the crystallinity of the first seed compound semiconductors 108 causes an increase in the crystallinity of the second seed compound semiconductors 110 having the specified surfaces of the first seed compound semiconductors 108 as seed surfaces. This in turn results in an increase in the crystallinity of the laterally grown compound semiconductor layers 112 having the specified surfaces of the second seed compound semiconductors 110 as seed surfaces. Accordingly, an increase in the crystallinity of the active layer of the electronic device formed on the laterally grown compound semiconductor layers 112 and an increase in the performance of the electronic device formed on the low-cost silicon wafer 102 is achieved.

Furthermore, in the electronic device 100 described above, the laterally grown compound semiconductor layers 112 are grown on the insulating films 104. In other words, the electronic device 100 has the same configuration as an SOI (Silicon On Insulator). Accordingly, the floating capacitance of the electronic device 100 is decreased and the operational speed can be improved. In addition, the leak current to the silicon wafer 102 can be decreased.

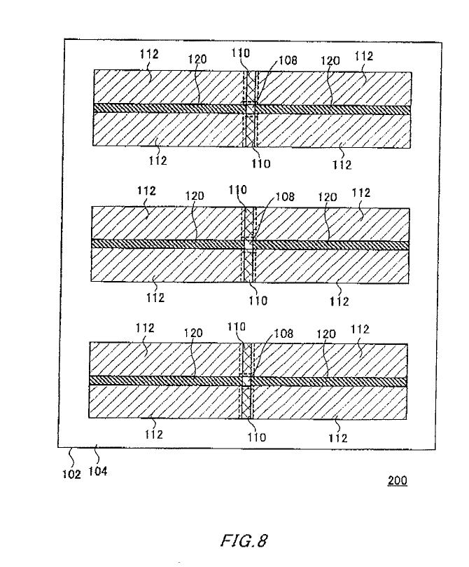

FIG. 8 is an exemplary planar view of another electronic device 200 according to an embodiment of the present invention. In FIG. 8, the gate electrodes and the source/drain electrodes are omitted. In the electronic device 200, the laterally grown compound semiconductor layers 112 include defect regions 120 containing defects. The defect regions 120 are generated from the open portions 105 formed in the first seed compound semiconductors 108, and the arrangement thereof is controlled by forming the open portions 105 at prescribed intervals. Here, the prescribed intervals are designed according to the objective of the electronic device 200, and may include, for example, forming a plurality of open portions 105 at uniform intervals, forming the open portions 105 at regular intervals, and forming the open portions 105 at periodic intervals.

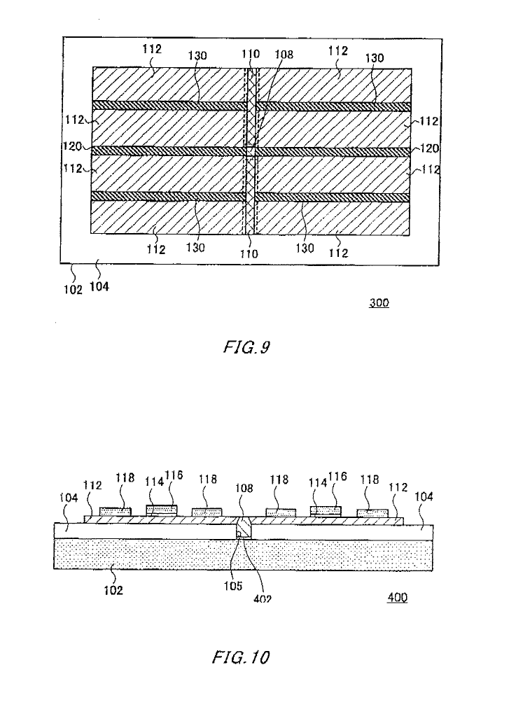

FIG. 9 is an exemplary planar view of another electronic device 300 according to an embodiment of the present invention. In FIG. 9, the gate electrodes and the source/drain electrodes are omitted. In the electronic device 300, the laterally grown compound semiconductor layers 112 include defect regions 130 containing defects, in addition to the defect regions 120 of the electronic device 200. The arrangement of the defect regions 130 is controlled by defect cores that are formed at prescribed intervals on the insulating films 104 or the seed surfaces of the second seed compound semiconductors 110.

The defect cores can be generated by forting physical grooves or the like in the seed surfaces or the insulating films 104, for example. This physical groove can be formed by mechanical scratching, friction, ion implantation, or the like. Here, the prescribed intervals are designed according to the objective of the electronic device 300, and may include, for example, forming a plurality of defect cores at uniform intervals, forming the defect cores at regular intervals, and forming the defect cores at periodic intervals.

The defect regions 120 and 130 are regions that include many defects, are formed intentionally on the laterally grown compound semiconductors, and may be formed during the crystal-growth of the laterally grown compound semiconductor layers 112. By forming the defect regions 120, the defects of the laterally grown compound semiconductor layers 112 can be concentrated in the defect regions 120 and 130, thereby decreasing the stress on regions of the laterally grown compound semiconductor layers 112 other than the defect regions 120 and 130, resulting in improved crystallinity. The electronic device can be formed on the defect-free regions, which are regions other than the defect regions 120 and 130. The term “defect-free regions” refers to regions that include absolutely no defects and to regions with lower defect density than the defect regions 120.

FIG. 10 is an exemplary cross-sectional view of another electronic device 400 according to an embodiment of the present invention. FIG. 10 is a cross section taken along the line A-A in FIG. 1. Aside from including a compound semiconductor buffer layer 402 in the open portion 105, the electronic device 400 is the same as the electronic device 100. The compound semiconductor buffer layer 402 may be a GaAs layer formed at a temperature no greater than 550° C., preferably no greater than 500° C.

By forming the compound semiconductor buffer layer 402, the crystallinity of the first seed compound semiconductors 108 can be further increased. The seed compound semiconductor crystal may be formed after the surface of the compound semiconductor buffer layer 402 or the bottom of the open portion 105 is processed with a gas containing P, such as PH₃. As a result, the crystallinity of the first seed compound semiconductors 108 can be further increased.

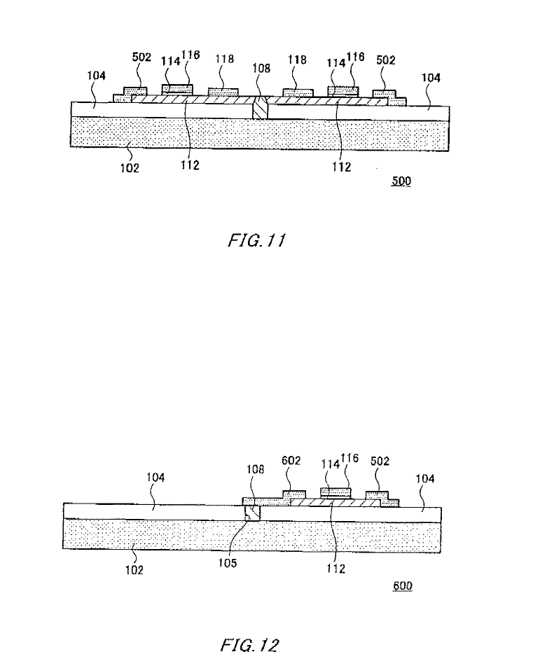

FIG. 11 is an exemplary cross-sectional view of another electronic device 500 according to an embodiment of the present invention. FIG. 11 is a cross section taken along the line A-A in FIG. 1. Aside from having a different arrangement for the source/drain electrode 502, the electronic device 500 is the same as the electronic device 100.

In the electronic device 500, the MOSFET, which are examples of active elements, include the source/drain electrodes 118 and the source/drain electrodes 502. The source/drain electrodes 502 are examples of first input/output electrodes, and the source/drain electrodes 118 are examples of the second input/output electrodes. The source/drain electrodes 502, which are examples of the first input/output electrodes, cover the growth surfaces of the laterally grown compound semiconductor layers 112. In other words, the source/drain electrodes 502 are also formed on the side surfaces of the laterally grown compound semiconductor layers 112.

By covering the side surfaces of the laterally grown compound semiconductor layers 112 with the source/drain electrodes 502, the input/output electrodes can be arranged in the movement direction of the carriers in the laterally grown compound semiconductor layers 112 or the active layers formed thereon, i.e. the carrier movement layers. As a result, the carrier movement is easily achieved to increase the performance of the electronic device 500.

FIG. 12 is an exemplary cross-sectional view of another electronic device 600 according to an embodiment of the present invention. FIG. 12 is a cross section taken along the line A-A in FIG. 1. Aside from having a different arrangement for the source/drain electrode 602, the electronic device 600 is the same as the electronic device 500. In the electronic device 600, the MOSFET, which is an example of an active element, includes the source/drain electrode 602 and the source/drain electrode 502. The source/drain electrode 602 is an example of the second input/output electrode.

In the electronic device 600, the laterally grown compound semiconductor layer 112 above the open portion 105 is removed by etching. The source/drain electrode 602 covers the side surface of the laterally grown compound semiconductor layer 112 that is exposed by the etching. As a result, the carrier movement is more easily achieved to further increase the performance of the electronic device 600.

Furthermore, the source/drain electrode 602 is connected to the silicon wafer 102 via the first seed compound semiconductor 108 of the open portion 105 exposed by the etching. As a result, one of the input/output terminals of the MOSFET is kept at the wafer potential, thereby achieving effects such as reducing noise, for example.

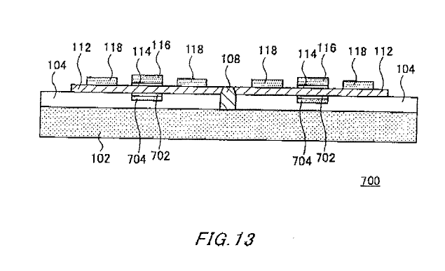

FIG. 13 is an exemplary cross-sectional view of another electronic device 700 according to an embodiment of the present invention. FIG. 13 is a cross section taken along the line A-A in FIG. 1. Aside from having lower gate insulating films 702 and lower gate electrodes 704, the electronic device 700 is the same as the electronic device 100. In the electronic device 700, the MOSFETs, which are examples of active elements, include the lower gate electrodes 704 and the gate electrodes 116 to control the voltage or current between the input and output.

The gate electrodes 116 and the lower gate electrodes 704 are examples of control electrodes. The lower gate electrodes 704 are arranged between the insulating films 104 and the laterally grown compound semiconductors 112, and the gate electrodes 116 are arranged on the sides of the laterally grown compound semiconductors 112 that are opposite the insulating films 104. The gate electrodes 116 and the lower gate electrodes 704 are formed facing each other.

By arranging the gate electrodes 116 and the lower gate electrodes 704 in the electronic device 700 in this way, a double gate configuration can be easily achieved. With a double gate configuration, the controlling ability of the gates is increased, thereby improving the switching performance and the like of the electronic device 700.

The above describes a MOSFET (metal-oxide-semiconductor field-effect transistor) as an example of the electronic device. However, the electronic device is not limited to a MOSFET, and can instead be an HEMT (High Electron Mobility Transistor), a pseudomorphic-HEMT, or the like. The electronic device 100 may also be a MESFET (Metal-Semiconductor Field Effect Transistor).

While the embodiments of the present invention have been described, the technical scope of the invention is not limited to the above described embodiments. It is apparent to persons skilled in the art that various alterations and improvements can be added to the above-described embodiments. It is also apparent from the scope of the claims that the embodiments added with such alterations or improvements can be included in the technical scope of the invention.

1. A semiconductor wafer comprising:
a silicon wafer;
an insulating film that is formed on the silicon wafer and that includes an open portion reaching the silicon wafer and having an aspect ratio of √3/3 or more;
a seed compound semiconductor crystal that is formed in the open portion and that protrudes beyond a top surface of the insulating film; and
a laterally grown compound semiconductor layer that is laterally grown on the insulating film with a specified surface of the seed compound semiconductor crystal as a seed surface.

2. The semiconductor wafer according to claim 1, wherein the open portion has a maximum width no greater than 5 μm in a direction parallel to a top surface of the silicon wafer.

3. The semiconductor wafer according to claim 1, wherein
the seed compound semiconductor crystal includes a first seed compound semiconductor that is formed in the open portion to protrude beyond the top surface of the insulating film and a second seed compound semiconductor that is laterally grown on the insulating film with a specified surface of the first seed compound semiconductor as a nucleus, and
the seed surface is a specified surface of the second seed compound semiconductor.

4. The semiconductor wafer according to claim 1, wherein
the laterally grown compound semiconductor layer or the seed compound semiconductor crystal includes defect regions that contain defects, and
arrangement of the defect regions is controlled by defect cores formed at prescribed intervals on the insulating film or on the seed surface.

5. The semiconductor wafer according to claim 1, wherein
the laterally grown compound semiconductor layer includes defect regions that contain defects, and
arrangement of the defect regions is controlled by forming a plurality or the open portions at prescribed intervals.

6. The semiconductor wafer according to claim 1, wherein
a plurality of the open portions are formed in the insulating film and a plurality of the laterally grown compound semiconductor layers are crystal-grown to be separated from each other on the insulating film, with specified surfaces of the seed compound semiconductor crystals formed in the open portions as seed surfaces.

7. The semiconductor wafer according to claim 1, wherein
the laterally grown compound semiconductor layer includes a group 2-6 compound semiconductor or a group 3-5 compound semiconductor.

8. A semiconductor wafer comprising:
a silicon wafer;
an insulating film that is formed on the silicon wafer and that includes an open portion having an aspect ratio √3/3 or more;
a seed compound semiconductor crystal that is formed in the open portion; and a compound semiconductor layer that is formed on the insulating film and that lattice matches or pseudo-lattice matches with the seed compound semiconductor crystal.

9. A semiconductor wafer comprising:
a silicon wafer;
an insulating film that is formed on the silicon wafer and that includes an opening reaching the silicon wafer and having an aspect ratio of √3/3 or more;
a compound semiconductor crystal that is formed in the opening and that protrudes beyond a top surface of the insulating film; and
a laterally grown compound semiconductor that is laterally grown on the insulating film with the compound semiconductor crystal as a seed.

10. The semiconductor wafer according to claim 9, wherein
the compound semiconductor crystal includes a first seed compound semiconductor that is formed in the opening to protrude beyond the top surface of the insulating film and a second seed compound semiconductor that is laterally grown on the insulating film with the first seed compound semiconductor as a nucleus.

11. A semiconductor wafer comprising:
a silicon wafer;
an insulating film that is formed on the silicon wafer and that includes an opening having an aspect ratio of √3/3 or more;
a compound semiconductor crystal that is formed in the opening; and
a compound semiconductor layer that is formed on the insulating film and that lattice matches or pseudo-lattice matches with the compound semiconductor crystal.

12. A semiconductor wafer comprising:
an insulating film that is formed on a silicon water and that includes an opening having an aspect ratio of √3/3 or more;
a first compound semiconductor that is formed in the opening; and
a second compound semiconductor that is grown at least on the insulating film with the first compound semiconductor as a nucleus.

13. A method of manufacturing a semiconductor wafer, comprising:
forming an insulating film on a silicon wafer;
forming, in the insulating film, an open portion reaching the silicon wafer and having an aspect ratio of √3/3 or more;
forming a seed compound semiconductor crystal in the open portion that protrudes beyond a top surface of the insulating film; and
laterally growing a laterally grown compound semiconductor layer on the insulating film with a specified surface of the seed compound semiconductor crystal as a seed surface.

14. The method of manufacturing a semiconductor wafer according to claim 13, wherein forming the seed compound semiconductor crystal includes:
forming in the open portion a first seed compound semiconductor that protrudes beyond the top surface of the insulating film; and
laterally growing a second seed compound semiconductor on the insulating film, with a specified surface of the first seed compound semiconductor as a nucleus, and forming specified surface of the second seed compound semiconductor as the seed surface.

15. The method of manufacturing a semiconductor wafer according to claim 14, further comprising forming defect cores at prescribed intervals on the seed surface of the seed compound semiconductor crystal, the seed surface of the second seed compound semiconductor, or the insulating film.

16. A method of manufacturing a semiconductor wafer, comprising: forming an insulating film on a silicon wafer,
forming, in the insulating film, an opening, reaching the silicon wafer and having an aspect ratio of √3/3 or more;
forming a compound semiconductor crystal in the opening that protrude beyond a top surface of the insulating film; and
laterally growing a laterally grown compound semiconductor on the insulating film, with the compound semiconductor crystal as a seed.

17. A method of manufacturing a semiconductor wafer, comprising: forming, on a silicon wafer, an insulating film that includes an opening having an aspect ratio of √3/3 or more;
forming a first compound semiconductor in the opening; and
forming a second compound semiconductor at least on the insulating film with the first compound semiconductor as a nucleus.

18. An electronic device comprising:
a silicon wafer;
an insulating film that is formed on the silicon wafer and that includes an open portion reaching the silicon wafer and having an aspect ratio of √3/3 or more;
a seed compound semiconductor crystal that is formed in the open portion and that protrudes beyond a top surface of the insulating film;
a laterally grown compound semiconductor layer that is laterally grown on the insulating film with a specified surface of the seed compound semiconductor crystal as a seed surface; and
an active element that has an active region and that is formed on a defect-free region of the laterally grown compound semiconductor layer.

19. The electronic device according to claim 18, wherein the active element has a first input/output electrode and a second input/output electrode, and
the first input/output electrode covers a growth surface of the laterally grown compound semiconductor layer.

20. The electronic device according to claim 18, wherein
the active element has a first input/output electrode and a second input/output electrode,
the laterally grown compound semiconductor layer in a region containing the open portion is removed by etching, and
the second input/output electrode covers a side surface of the laterally grown compound semiconductor layer that is exposed by the etching.

21. The electronic device according to claim 20, wherein
the second input/output electrode is connected to the silicon wafer via the seed compound semiconductor crystal formed in the open portion of the insulating film exposed by the etching.

22. The electronic device according to claim 18, wherein
the active element has control electrodes that control voltage or current between input and output, and
the control electrodes are formed (i) between the insulating film and the laterally grown compound semiconductor layer and (ii) on a side of the laterally grown compound semiconductor layer that is opposite the insulating film, in a manner to face each other.

23. The electronic device according to claim 18, wherein
a plurality of the active elements are connected to each other.

24. An electronic device comprising:
a silicon wafer;
an insulating film that is formed on the silicon wafer and that includes an opening reaching the silicon wafer and having an aspect ratio of √3/3 or more;
a compound semiconductor crystal that is formed in the opening and that protrudes beyond a top surface of the insulating film;
a laterally grown compound semiconductor that is laterally grown on the insulating film with the compound semiconductor crystal as a seed; and
an active element having an active region on the laterally grown compound semiconductor.

25. An electronic device comprising:
an insulating film that is formed on a silicon wafer and that includes an opening having an aspect ratio of √3/3 or more;
a first compound semiconductor that is formed in the opening;
a second compound semiconductor that is grown at least on the insulating film with the first compound semiconductor as a nucleus; and
an active element having an active region on the second compound semiconductor.
